(19) United States
(12) Patent Application Publication
(10) Pub. No.: US 2024/0112966 A1
(43) Pub. Date: Apr. 4, 2024

(54) MULTISIDED INTEGRATED CIRCUIT ASSEMBLY

(71) Applicant: Azimuth Industrial Company, Inc., Union City, CA (US)

(72) Inventor: David Lee, Palo Alto, CA (US)

(73) Assignee: Azimuth Industrial Company, Inc., Union City, CA (US)

(21) Appl. No.: 18/478,837

(22) Filed: Sep. 29, 2023

Related U.S. Application Data
(60) Provisional application No. 63/412,323, filed on Sep. 30, 2022.

(51) Int. Cl. H01L 23/13; H01L 23/00

(52) U.S. Cl. CPC H01L 23/13; H01L 24/08; H01L 24/09; H01L 24/16; H01L 24/81; H01L 2224/08238; H01L 2224/09181; H01L 2224/09183; H01L 2224/16168; H01L 2224/16227; H01L 2224/16238; H01L 2224/80895; H01L 2224/81191; H01L 2924/15153

(57) ABSTRACT

Implementations generally relate to a multisided integrated circuit assembly. In some implementations, an assembly includes an integrated circuit (IC) chip having IC contact terminals. The assembly further includes surface interfaces coupled to the IC chip, where at least one first surface interface and at least one second surface interface of the surface interfaces are configured to couple to a motherboard. The assembly further includes surface contact terminals on the surface interfaces, where the surface contact terminals couple to the IC contact terminals, and where at least one subset of the surface contact terminals also couples to at least one subset of motherboard contact terminals on the motherboard.

### CROSS REFERENCE TO RELATED APPLICATIONS

This application claims priority from U.S. Provisional Patent Application No. 63/412,323, entitled “MULTISIDED INTEGRATED CIRCUIT ASSEMBLY,” filed Sep. 30, 2022, which is hereby incorporated by reference as if set forth in full in this application for all purposes.

### BACKGROUND

A ball grid array (BGA) is a type of surface-mount packaging that is used for integrated circuits. BGA packages are used to permanently mount devices such as microprocessors onto a motherboard. A BGA can provide more interconnection pins than can be put on a dual in-line or flat package. Conventionally, one side of a BGA package may be mounted onto a motherboard. In some instances, the opposite of a BGA package may have contact terminals for testing.

### SUMMARY

Implementations generally relate to a multisided integrated circuit (IC) chip assembly. In various implementations, an assembly includes an integrated circuit (IC) chip having IC contact terminals. The assembly further includes surface interfaces coupled to the IC chip, where at least one first surface interface and at least one second surface interface of the surface interfaces are configured to couple to a motherboard. The assembly further includes surface contact terminals on the surface interfaces, where the surface contact terminals couple to the IC contact terminals, and where at least one subset of the surface contact terminals also couples to at least one subset of motherboard contact terminals on the motherboard.

With further regard to the assembly, in some implementations, the surface interfaces include six surface interfaces, and where the six surface interfaces form a cubic IC package. In some implementations, the assembly further includes conductive tracing on the surface interfaces, where the conductive tracing couples to at least one subset of the surface contact terminals, and where the conductive tracing enables the at least one subset of the surface contact terminals coupled thereto to couple to the at least one subset of motherboard contact terminals. In some implementations, the surface interfaces form a cubic IC package, where solder balls are coupled to surface contact terminals on at least one surface interface of the cubic IC package, and where the solder balls enable the surface contact terminals coupled thereto to couple to the at least one subset of motherboard contact terminals. In some implementations, the surface interfaces form a cubic IC package, and where the cubic IC package is configured to be inserted at least partially into a cavity of the motherboard. In some implementations, at least five surface interfaces of the surface interfaces are configured to couple to the motherboard, and where at least one subset of surface contact terminals on the at least five surface interfaces couples to the at least one subset of motherboard contact terminals. In some implementations, the assembly further includes at least one third surface interface of the surface interfaces is configured to couple to an auxiliary printed circuit board (PCB).

In some implementations, a system includes one or more processors, and includes logic encoded in one or more non-transitory computer-readable storage media for execution by the one or more processors. When executed, the logic is operable to cause the one or more processors to perform operations including: obtaining an integrated circuit (IC) chip; providing surface interfaces, where at least one first surface interface and at least one second surface interface of the surface interfaces are configured to couple to a motherboard; providing surface contact terminals on the surface interfaces; coupling the surface contact terminals to IC contact terminals on the IC chip, where at least one subset of the surface contact terminals also couples to at least one subset of motherboard contact terminals on the motherboard; and coupling the surface interfaces to the IC chip.

With further regard to the system, in some implementations, the surface interfaces include six surface interfaces, and where the six surface interfaces form a cubic IC package. In some implementations, the system further includes conductive tracing on the surface interfaces, where the conductive tracing couples to at least one subset of the surface contact terminals, and where the conductive tracing enables the at least one subset of the surface contact terminals coupled thereto to couple to the at least one subset of motherboard contact terminals. In some implementations, the surface interfaces form a cubic IC package, where solder balls are coupled to surface contact terminals on at least one surface interface of the cubic IC package, and where the solder balls enable the surface contact terminals coupled thereto to couple to the at least one subset of motherboard contact terminals. In some implementations, the surface interfaces form a cubic IC package, and where the cubic IC package is configured to be inserted at least partially into a cavity of the motherboard. In some implementations, at least five surface interfaces of the surface interfaces are configured to couple to the motherboard, and where at least one subset of surface contact terminals on the at least five surface interfaces couples to the at least one subset of motherboard contact terminals. In some implementations, at least one third surface interface of the surface interfaces is configured to couple to an auxiliary printed circuit board (PCB).

In some implementations, a method includes: obtaining an integrated circuit (IC) chip; providing surface interfaces, where at least one first surface interface and at least one second surface interface of the surface interfaces are configured to couple to a motherboard; providing surface contact terminals on the surface interfaces; coupling the surface contact terminals to IC contact terminals on the IC chip, where at least one subset of the surface contact terminals also couples to at least one subset of motherboard contact terminals on the motherboard; and coupling the surface interfaces to the IC chip.

With further regard to the method, in some implementations, the surface interfaces include six surface interfaces, and where the six surface interfaces form a cubic IC package. In some implementations, the method further includes coupling conductive tracing to the surface interfaces, where the conductive tracing couples to at least one subset of the surface contact terminals, and where the conductive tracing enables the at least one subset of the surface contact terminals coupled thereto to couple to the at least one subset of motherboard contact terminals. In some implementations, the surface interfaces form a cubic IC package, where solder balls are coupled to surface contact terminals on at least one surface interface of the cubic IC package, and where the solder balls enable the surface contact terminals coupled thereto to couple to the at least one subset of motherboard contact terminals. In some implementations, the surface interfaces form a cubic IC package, and where the cubic IC package is configured to be inserted at least partially into a cavity of the motherboard. In some implementations, at least five surface interfaces of the surface interfaces are configured to couple to the motherboard, and where at least one subset of surface contact terminals on the at least five surface interfaces couples to the at least one subset of motherboard contact terminals.

A further understanding of the nature and the advantages of particular implementations disclosed herein may be realized by reference of the remaining portions of the specification and the attached drawings.

### BRIEF DESCRIPTION OF THE DRAWINGS

FIG. 1 is a block diagram of an example multisided integrated circuit (IC) chip assembly, according to various implementations.

FIG. 2 is a block diagram of an example multisided IC chip assembly of FIG. 1, where an IC chip contained therein is shown, according to various implementations.

FIG. 3 is a side-view block diagram of an example environment, where a multisided IC chip assembly is positioned to be inserted into a cavity of a motherboard, according to various implementations.

FIG. 4 is a side-view block diagram of example environment of FIG. 3, where multisided IC chip assembly is inserted into cavity of motherboard, according to various implementations.

FIG. 5 is an example flow diagram for providing a multisided IC chip assembly, according to some implementations.

FIG. 6 is an example layout diagram including multiple surface interfaces for a multisided IC chip assembly, according to some implementations.

FIG. 7 is a block diagram of an example computer system, which may be used for some implementations described herein.

### DETAILED DESCRIPTION

Implementations described herein provide a multisided integrated circuit (IC) chip assembly. As described in more detail herein, in various implementations, a multisided IC chip assembly includes an IC chip having IC contact terminals. The assembly also includes surface interfaces coupled to the IC chip, where at least one first surface interface and at least one second surface interface of the surface interfaces are configured to couple to a motherboard. In various implementations, the surface interfaces include six surface interfaces, and where the six surface interfaces form a cubic IC package. The assembly also includes surface contact terminals on the surface interfaces, where the surface contact terminals couple to the IC contact terminals, and where at least one subset of the surface contact terminals also couples to at least one subset of motherboard contact terminals on the motherboard. In various implementations, the cubic IC package is configured to be inserted at least partially into a cavity of the motherboard.

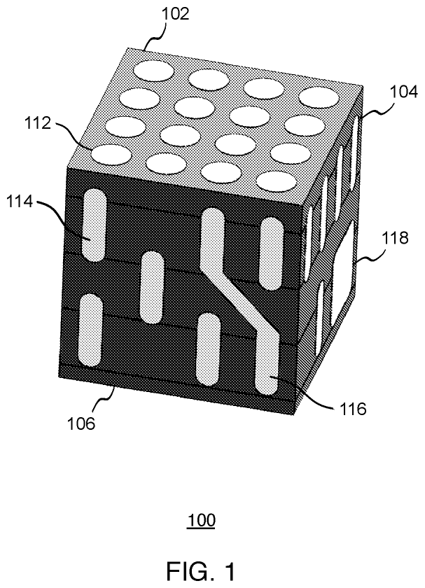

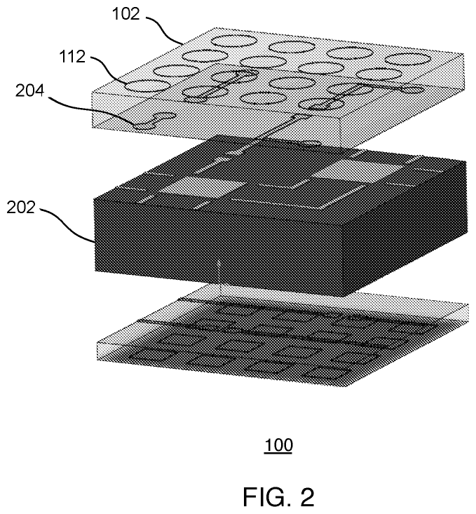

FIG. 1 is a block diagram of an example multisided integrated circuit (IC) chip assembly 100, according to various implementations. In various implementations, multisided IC chip assembly 100, or assembly 100 includes an IC chip (shown in FIG. 2) contained in surface interfaces such as surface interfaces 102, 104, and 106. In various implementations, the surface interfaces include six surface interfaces, where the six surface interfaces form a cubic IC package. The other surface interfaces of assembly 100 are hidden from view.

As shown, assembly 100 includes surface contact terminals such as surface contact terminals 112, 114, 116, and 118 on the surface interfaces. As described in more detail herein, the surface contact terminals couple to IC contact terminals (shown in FIG. 2). The particular shapes of the surface contact terminals may vary, depending on the particular implementation. For example, surface contact terminal 112 has a circular shape. Surface contact terminal 114 has a rounded rectangular shape. Surface contact terminal 116 has a shape similar to two rounded rectangular shapes having a trace line connecting the two. Surface contact terminal 118 has a square shape.

In some implementations, assembly 100 may include conductive tracing on the surface interfaces, where the conductive tracing couples to at least one subset of the surface contact terminals. For example, in some implementations, a given surface contact terminal such as surface contact terminal 114 may be smaller in size and shape than shown, where its size and/or shape shown is modified as a result of conductive tracing applied on the surface of surface interface 106. Alternatively, surface contact terminal 114 may be indeed the size and shape shown and integrated into surface interface 106. In either case, the resulting conductive terminal is referred to as surface contact terminal 114. In various implementations, the conductive tracing enables the surface contact terminals coupled thereto to more easily couple to corresponding subsets of motherboard contact terminals (not shown). This is advantageous where motherboard contact terminals may vary in configuration. This is also advantageous to provide more placement or alignment tolerance of motherboard contact terminals. In other words, this flexibility improves the performance of assembly 100 overall.

In another example of conductive tracing, in some implementations, a given surface contact terminal such as surface contact terminal 116 may be two different surface contact terminals (e.g., each similar in size and shape as surface contact terminal 114), where a conductive trace is applied on the surface of surface interface 106 in order to connect the two surface contact terminals. Alternatively, surface contact terminal 116 may be indeed the size and shape shown and integrated into surface interface 106. In either case, the resulting conductive terminal is referred to as surface contact terminal 116.

In various implementations, the system may couple solder balls to surface contact terminals on at least one surface interface of the cubic IC package. In the example shown, surface contact terminal 112 and the like-shaped surface contact terminals are circular and configured for placement of solder balls. The solder balls enable the surface contact terminals coupled thereto (e.g., surface contact terminal 112, etc.) to couple to the at least one subset of motherboard contact terminals (not shown). This may be the scenario, where the assembly functions similarly to a flip-chip. For example, the system may position surface interface 102 at the bottom and lower assembly 100 onto a motherboard, where surface interface 102 couples to the motherboard. More specifically, surface interface 102 couples to the motherboard in that the solder balls coupled to the surface contact terminals engage motherboard contact terminals.

Accordingly, at least one surface interface such as surface interface 102 of assembly 100 is configured to couple to a motherboard. In particular, surface contact terminals of the surface interface are configured to couple to corresponding motherboard contact terminals. As described in more detail herein, in various implementations, assembly 100 is configured to be inserted at least partially into a cavity of the motherboard, where the sides or walls of the cavity have motherboard contact terminals facing toward and engaging surface contact points (e.g., surface contact points 114 and 116, etc.). As such, at least one other surface interface such as surface interface 106 is configured to couple to the motherboard. In various implementations, multiple surface interfaces such as surface interface 102, 104, 106, and the surface interfaces opposite to surface interfaces 104 and 106 may couple to a motherboard. More specifically, some of the surface contact terminals of these surface interfaces couple to corresponding motherboard contact terminals.

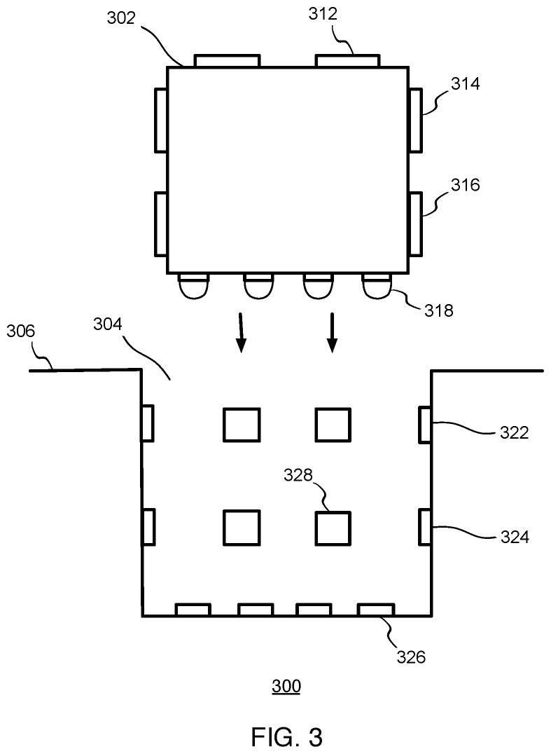

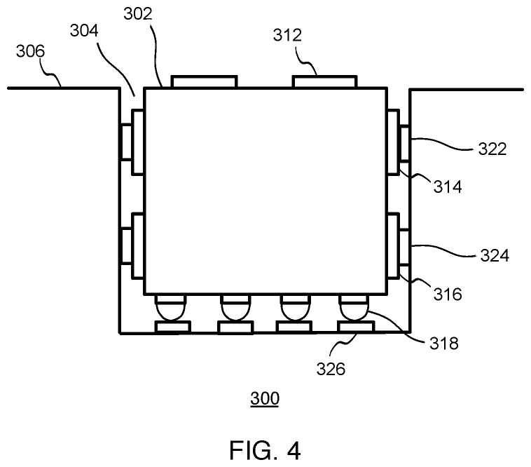

Further example implementations directed to assembly 100 are described in more detail herein in connection with FIG. 2, for example. Further example implementations directed to assembly 100 being inserted into a cavity of a motherboard are described in more detail herein in connection with FIGS. 3 and 4, for example.

FIG. 2 is a block diagram of the example multisided IC chip assembly 100 of FIG. 1, where an IC chip 202 contained therein is shown, according to various implementations. Multisided IC chip assembly 100 is the same as that shown in FIG. 1, except that assembly 100 shown in FIG. 2 is translucent for ease of illustration. Shown is surface interface 102 having surface contact terminals such as surface contact terminal 112. For ease of illustration, the surface interfaces that are contiguous with surface interface 102 are not shown in order to more clearly illustrate IC chip 202.

In various implementations, the surface interfaces couple to IC chip 202. The coupling may be achieved mechanically by way of direct contact and adhesion, posts, an assembly overmold, by any other suitable means, or combination thereof. In various implementations, the surface contact terminals such as surface contact terminal 112 couple to the IC contact terminals.

In various implementations, the surface contact terminals are integrated into a respective surface interface such that portions of the surface contact terminals that are located at or exposed at the inside of assembly 100 may be electronically coupled to corresponding IC contact terminals on the IC chip. For example, surface contact terminals located at the inside of assembly 100 may include surface contact terminals that are exposed and/or protruding at the internal or interior side of surface interfaces and that are accessible from the inside of a completed IC package.

In various implementations, the system may apply conductive tracing such as conductive tracing 204 on the interior side of at least some of surface interfaces, where at least some of the surface contact terminals couple to corresponding IC contact terminals via the conductive tracing. In various implementations, the conductive tracing may enable some of the surface contact terminals to better route to corresponding IC contact terminals.

The portions of surface contact terminals that are located at or exposed at the outside of assembly 100 may be electronically coupled to a corresponding motherboard contact terminal or other contact terminal on an auxiliary PCB (not shown). For example, surface contact terminals located at the outside of assembly 100 may include surface contact terminals that are exposed and/or protruding at the external or exterior side of surface interfaces and that are accessible from the outside of a completed IC package. As indicated above, in various implementations, surface contact terminals of the surface interface are configured to couple to corresponding motherboard contact terminals external to assembly 100.

While various implementations are described herein in the context of a multisided IC chip assembly that is shaped in the form of a cube, these implementations may apply to other shapes. The particular shape may vary, depending on the particular implementation. For example, implementations may also apply to multisided IC assemblies that are shaped in forms of cuboids, cylinders, prisms, (e.g., hexagonal prisms, triangular prisms, etc.), pyramids (e.g., square-based pyramids, triangular-based pyramids, etc.), cones, spheres, etc.

FIG. 3 is a side-view block diagram of an example environment 300, where a multisided IC chip assembly 302 is positioned to be inserted into a cavity 304 of a motherboard 306, according to various implementations. In this example implementation, multisided IC chip assembly 302, or assembly 302, has surface interfaces that are configured in the form a cubic IC package. Assembly 302 has surface contact terminals such as surface contact terminals 312, 314, and 316 on the surface interfaces. Also, shown are solder balls such as solder ball 318 coupled to one side of assembly 302. For ease of illustration, uniform shapes and configurations of surface contact terminals are shown. As indicative herein, the shapes, configurations, and positions of the surface contact terminals may vary, depending on the particular implementation. Also, for ease of illustration, the surface contact terminals are shown as protruding outward. In some implementations, the surface contact terminals may be flush with the surface interfaces.

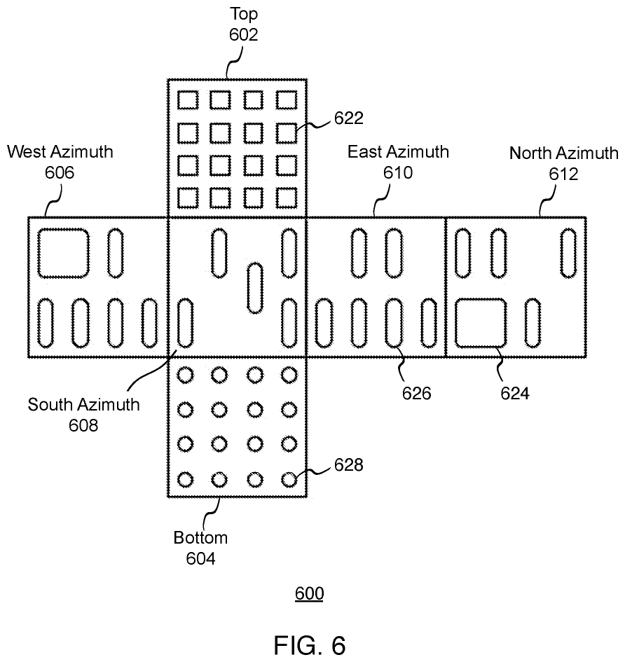

In various implementations, cavity 304 of motherboard 306 has surfaces or walls that have motherboard contact terminals such as motherboard contact terminals 322, 324, 326, and 328 protruding away from the walls. In various implementations, the shapes, configurations, and placement of the motherboard contact terminals may vary, depending on the particular implementation. Similarly, as indicated above, the shapes, configurations, and placement of the surface contact terminals and solder balls of assembly 302 may vary, depending on the particular implementation. For ease of illustration, example contact terminals and example surfaces of assembly 302 and motherboard 306 are shown. In various implementations, surface contact terminals may be positioned on up to all six sides of assembly 302 with corresponding contact terminals on corresponding surfaces of motherboard 306. Further example implementations directed to shapes, configurations, and placement of contact terminals of assembly 302 are described in more detail herein, such as in FIG. 6, for example.

As indicated herein, in various implementations, the cubic IC package is configured to be inserted at least partially into cavity 304 of motherboard 306. When assembly 302 is inserted into cavity 304 of motherboard 306, the surface contact terminals on the bottom surface interface and as well as surface contact terminals on the side surface interfaces are configured to couple to the motherboard contact terminals.

FIG. 4 is a side-view block diagram of example environment 300 of FIG. 3, where multisided IC chip assembly 302 is inserted into cavity 304 of motherboard 306, according to various implementations. In this example implementation, at least five surface interfaces of assembly 302 are configured to couple to motherboard 306. Also, at least a subset of surface contact terminals on the five surface interfaces couples to at least a subset of the motherboard contact terminals. Not all of the surface contact terminals need to couple to corresponding motherboard contact terminals. The particular contact terminal couplings may vary, depending on the particular implementation.

As shown, one surface interface (e.g., the bottom surface interface) of assembly 302 having solder balls coupled thereto engages with one surface (e.g., the floor) of cavity 304. Also, four surface interfaces of assembly 302 on the sides engage four corresponding surfaces of the, e.g., four walls of cavity 304. In various implementations, surface contact terminals of each of the five surface interfaces couples to one or more subsets of the motherboard contact terminals. The particular surface contact terminals of assembly 302 that couple to motherboard contact terminals of motherboard 306 may vary, depending on the particular implementation.

As shown, when assembly 302 is inserted into cavity 304 of motherboard 306, the solder balls couple to or engage the motherboard contact terminals. For example, solder ball 318 is shown coupled to motherboard contact terminal 326. Also, surface contact terminals 314 and 316 couple to motherboard contact terminals 322 and 324, respectively.

In various implementations, at least one surface interface such as the top surface interface remains exposed and accessible. As such, that exposed surface interface is configured to couple to an auxiliary printed circuit board (PCB) (not shown). For example, a PCB may be placed over the surface interface that has exposed surface contact terminals such as surface contact terminal 312 such that the PCB contact terminal(s) couple to one or more of the exposed surface contact terminals. Alternatively, in some implementations, a wire bond may couple some of those exposed surface contact terminals to a motherboard terminal when assembly 302 is inserted into cavity 304 of motherboard 306. The particular couplings may vary, depending on the implementation.

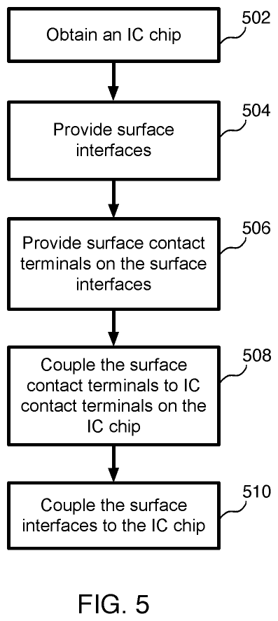

FIG. 5 is an example flow diagram for providing a multisided IC chip assembly, according to some implementations. A method is initiated at block 502, where a system obtains an IC chip.

At block 504, the system provides surface interfaces. In various implementations, the surface interfaces include six surface interfaces, where the six surface interfaces form a cubic IC package.

FIG. 6 is an example layout diagram 600 including multiple surface interfaces for a multisided IC chip assembly, according to some implementations. Shown is a top surface interface 602 (labeled Top), a bottom surface interface 604 (labeled Bottom), a west azimuth surface interface 606 (labeled West Azimuth), a west azimuth surface interface 606 (labeled South Azimuth), an east azimuth surface interface 610 (labeled East Azimuth), and a north azimuth surface interface 612 (labeled North Azimuth).

At block 506, the system provides surface contact terminals on the surface interfaces. In various implementations, the surface contact terminals provided may be copper contact terminals.

At block 508, the system couples the surface contact terminals to IC contact terminals on the IC chip. Referring still to FIG. 6, also shown on each surface interface are a variety of surface contact terminals such as surface contact terminals 622, 624, 626, and 628. The particular shapes and configurations of the surface contact terminals may vary, depending on the particular implementation. In various implementations, the system may apply conductive tracing on the surface interfaces, where the conductive tracing couples to at least one subset of the surface contact terminals. In various implementations, the conductive tracing enables the surface contact terminals coupled thereto to couple to the at least a subset of motherboard contact terminals. Referring to FIG. 1, surface contact terminal 116 is an example of two surface contact terminals that are joined by conductive tracing, in some implementations.

At block 510, the system couples the surface interfaces to the IC chip. Example implementations directed to surface interfaces coupled to an IC chip are described herein in connection with FIG. 2, for example. As shown in the example implementation of FIG. 2, the surface interfaces may form a cubic IC package, and where the cubic IC package is configured to be inserted at least partially into a cavity of the motherboard. In various implementations, when the cubic IC package is inserted into the cavity of the motherboard, surface contact terminals on the bottom surface interface and as well as surface contact terminals on the side surface interfaces of the assembly are configured to couple to corresponding motherboard contact terminals on the motherboard. In some implementations, it is possible that not all surface contact terminals of a given assembly are needed for a particular application. In some implementations, it is possible that more surface contact terminals of the assembly are needed, depending on the particular application. As such, there may be some scenarios where the number of surface contact terminals of the assembly and the number of contact terminals of the mother board differ where some contact terminals are unused based on the particular application and/or implementation.

Although the steps, operations, or computations may be presented in a specific order, the order may be changed in particular implementations. Other orderings of the steps are possible, depending on the particular implementation. In some particular implementations, multiple steps shown as sequential in this specification may be performed at the same time. Also, some implementations may not have all of the steps shown and/or may have other steps instead of, or in addition to, those shown herein.

Implementations described herein provide various benefits. For example, implementations enable more surfaces of an IC package to contain more contact terminals for connection to a motherboard and to additional printed circuit boards.

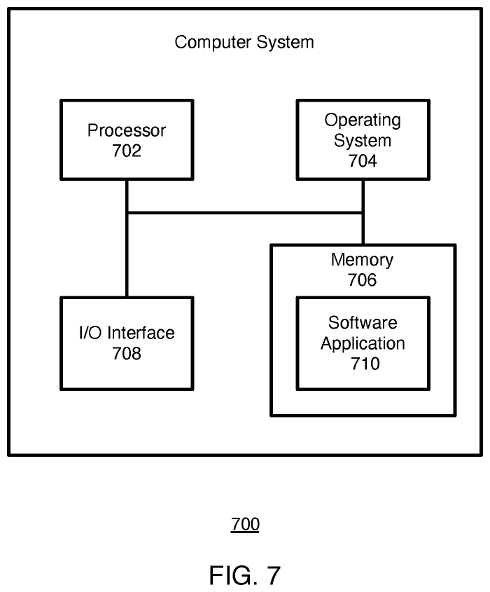

FIG. 7 is a block diagram of an example computer system 700, which may be used for some implementations described herein. For example, computer system 700 may be used to perform implementations described herein. In some implementations, computer system 700 may include a processor 702, an operating system 704, a memory 706, and an input/output (I/O) interface 708. In various implementations, processor 702 may be used to implement various functions and features described herein, as well as to perform the method implementations described herein. While processor 702 is described as performing implementations described herein, any suitable component or combination of components of computer system 700 or any suitable processor or processors associated with computer system 700 or any suitable system may perform the steps described. Implementations described herein may be carried out on a user device, on a server, or a combination of both.

Computer system 700 also includes a software application 710, which may be stored on memory 706 or on any other suitable storage location or computer-readable medium. Software application 710 provides instructions that enable processor 702 to perform the implementations described herein and other functions. Software application may also include an engine such as a network engine for performing various functions associated with one or more networks and network communications. The components of computer system 700 may be implemented by one or more processors or any combination of hardware devices, as well as any combination of hardware, software, firmware, etc.

For ease of illustration, FIG. 7 shows one block for each of processor 702, operating system 704, memory 706, I/O interface 708, and software application 710. These blocks 702, 704, 706, 708, and 710 may represent multiple processors, operating systems, memories, I/O interfaces, and software applications. In various implementations, computer system 700 may not have all of the components shown and/or may have other elements including other types of components instead of, or in addition to, those shown herein.

Although the description has been described with respect to particular implementations thereof, these particular implementations are merely illustrative, and not restrictive. Concepts illustrated in the examples may be applied to other examples and implementations.

In various implementations, software is encoded in one or more non-transitory computer-readable media for execution by one or more processors. The software when executed by one or more processors is operable to perform the implementations described herein and other functions.

Any suitable programming language can be used to implement the routines of particular implementations including C, C++, C#, Java, JavaScript, assembly language, etc. Different programming techniques can be employed such as procedural or object oriented. The routines can execute on a single processing device or multiple processors. Although the steps, operations, or computations may be presented in a specific order, this order may be changed in different particular implementations. In some particular implementations, multiple steps shown as sequential in this specification can be performed at the same time.

Particular implementations may be implemented in a non-transitory computer-readable storage medium (also referred to as a machine-readable storage medium) for use by or in connection with the instruction execution system, apparatus, or device. Particular implementations can be implemented in the form of control logic in software or hardware or a combination of both. The control logic when executed by one or more processors is operable to perform the implementations described herein and other functions. For example, a tangible medium such as a hardware storage device can be used to store the control logic, which can include executable instructions.

Particular implementations may be implemented by using a programmable general purpose digital computer, and/or by using application specific integrated circuits, programmable logic devices, field programmable gate arrays, optical, chemical, biological, quantum or nanoengineered systems, components and mechanisms. In general, the functions of particular implementations can be achieved by any means as is known in the art. Distributed, networked systems, components, and/or circuits can be used. Communication, or transfer, of data may be wired, wireless, or by any other means.

A “processor” may include any suitable hardware and/or software system, mechanism, or component that processes data, signals or other information. A processor may include a system with a general-purpose central processing unit, multiple processing units, dedicated circuitry for achieving functionality, or other systems. Processing need not be limited to a geographic location, or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory. The memory may be any suitable data storage, memory and/or non-transitory computer-readable storage medium, including electronic storage devices such as random-access memory (RAM), read-only memory (ROM), magnetic storage device (hard disk drive or the like), flash, optical storage device (CD, DVD or the like), magnetic or optical disk, or other tangible media suitable for storing instructions (e.g., program or software instructions) for execution by the processor. For example, a tangible medium such as a hardware storage device can be used to store the control logic, which can include executable instructions. The instructions can also be contained in, and provided as, an electronic signal, for example in the form of software as a service (SaaS) delivered from a server (e.g., a distributed system and/or a cloud computing system).

It will also be appreciated that one or more of the elements depicted in the drawings/figures can also be implemented in a more separated or integrated manner, or even removed or rendered as inoperable in certain cases, as is useful in accordance with a particular application. It is also within the spirit and scope to implement a program or code that can be stored in a machine-readable medium to permit a computer to perform any of the methods described above.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

Thus, while particular implementations have been described herein, latitudes of modification, various changes, and substitutions are intended in the foregoing disclosures, and it will be appreciated that in some instances some features of particular implementations will be employed without a corresponding use of other features without departing from the scope and spirit as set forth. Therefore, many modifications may be made to adapt a particular situation or material to the essential scope and spirit.

What is claimed is:

1. Assembly comprising:
an integrated circuit (IC) chip having IC contact terminals;
surface interfaces coupled to the IC chip, wherein at least one first surface interface and at least one second surface interface of the surface interfaces are configured to couple to a motherboard; and
surface contact terminals on the surface interfaces, wherein the surface contact terminals couple to the IC contact terminals, and wherein at least one subset of the surface contact terminals also couples to at least one subset of motherboard contact terminals on the motherboard.

2. The assembly of claim 1, wherein the surface interfaces comprise six surface interfaces, and wherein the six surface interfaces form a cubic IC package.

3. The assembly of claim 1, further comprising conductive tracing on the surface interfaces, wherein the conductive tracing couples to at least one subset of the surface contact terminals, and wherein the conductive tracing enables the at least one subset of the surface contact terminals coupled thereto to couple to the at least one subset of motherboard contact terminals.

4. The assembly of claim 1, wherein the surface interfaces form a cubic IC package, wherein solder balls are coupled to surface contact terminals on at least one surface interface of the cubic IC package, and wherein the solder balls enable the surface contact terminals coupled thereto to couple to the at least one subset of motherboard contact terminals.

5. The assembly of claim 1, wherein the surface interfaces form a cubic IC package, and wherein the cubic IC package is configured to be inserted at least partially into a cavity of the motherboard.

6. The assembly of claim 1, wherein at least five surface interfaces of the surface interfaces are configured to couple to the motherboard, and wherein at least one subset of surface contact terminals on the at least five surface interfaces couples to the at least one subset of motherboard contact terminals.

7. The assembly of claim 1, wherein at least one third surface interface of the surface interfaces is configured to couple to an auxiliary printed circuit board (PCB).

8. A system comprising:
one or more processors; and
logic encoded in one or more non-transitory computer-readable storage media for execution by the one or more processors and when executed operable to cause the one or more processors to perform operations comprising:
obtaining an integrated circuit (IC) chip;
providing surface interfaces, wherein at least one first surface interface and at least one second surface interface of the surface interfaces are configured to couple to a motherboard;
providing surface contact terminals on the surface interfaces;
coupling the surface contact terminals to IC contact terminals on the IC chip, wherein at least one subset of the surface contact terminals also couples to at least one subset of motherboard contact terminals on the motherboard; and
coupling the surface interfaces to the IC chip.

9. The system of claim 8, wherein the surface interfaces comprise six surface interfaces, and wherein the six surface interfaces form a cubic IC package.

10. The system of claim 8, further comprising conductive tracing on the surface interfaces, wherein the conductive tracing couples to at least one subset of the surface contact terminals, and wherein the conductive tracing enables the at least one subset of the surface contact terminals coupled thereto to couple to the at least one subset of motherboard contact terminals.

11. The system of claim 8, wherein the surface interfaces form a cubic IC package, wherein solder balls are coupled to surface contact terminals on at least one surface interface of the cubic IC package, and wherein the solder balls enable the surface contact terminals coupled thereto to couple to the at least one subset of motherboard contact terminals.

12. The system of claim 8, wherein the surface interfaces form a cubic IC package, and wherein the cubic IC package is configured to be inserted at least partially into a cavity of the motherboard.

13. The system of claim 8, wherein at least five surface interfaces of the surface interfaces are configured to couple to the motherboard, and wherein at least one subset of surface contact terminals on the at least five surface interfaces couples to the at least one subset of motherboard contact terminals.

14. The system of claim 8, wherein at least one third surface interface of the surface interfaces is configured to couple to an auxiliary printed circuit board (PCB).

15. A computer-implemented method comprising:
obtaining an integrated circuit (IC) chip;
providing surface interfaces, wherein at least one first surface interface and at least one second surface interface of the surface interfaces are configured to couple to a motherboard;
providing surface contact terminals on the surface interfaces;
coupling the surface contact terminals to IC contact terminals on the IC chip, wherein at least one subset of the surface contact terminals also couples to at least one subset of motherboard contact terminals on the motherboard; and
coupling the surface interfaces to the IC chip.

16. The method of claim 15, wherein the surface interfaces comprise six surface interfaces, and wherein the six surface interfaces form a cubic IC package.

17. The method of claim 15, further comprising coupling conductive tracing to the surface interfaces, wherein the conductive tracing couples to at least one subset of the surface contact terminals, and wherein the conductive tracing enables the at least one subset of the surface contact terminals coupled thereto to couple to the at least one subset of motherboard contact terminals.

18. The method of claim 15, wherein the surface interfaces form a cubic IC package, wherein solder balls are coupled to surface contact terminals on at least one surface interface of the cubic IC package, and wherein the solder balls enable the surface contact terminals coupled thereto to couple to the at least one subset of motherboard contact terminals.

19. The method of claim 15, wherein the surface interfaces form a cubic IC package, and wherein the cubic IC package is configured to be inserted at least partially into a cavity of the motherboard.

20. The method of claim 15, wherein at least five surface interfaces of the surface interfaces are configured to couple to the motherboard, and wherein at least one subset of surface contact terminals on the at least five surface interfaces couples to the at least one subset of motherboard contact terminals.
